(19) United States
(12) Patent Application Publication
(10) Pub. No.: US 2011/0003458 A1
(43) Pub. Date: Jan. 6, 2011

(54) METHOD OF FORMING DEVICE ISOLATION LAYER AND METHOD OF FABRICATING SEMICONDUCTOR DEVICE

(75) Inventors: Seung-jae Lee, Hwaseong-si (KR); Jin-gi Hong, Yongin-si (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/829,993

(22) Filed: Jul. 2, 2010

(30) Foreign Application Priority Data
Jul. 3, 2009 (KR) 10-2009-0060834

(51) Int. Cl. H01L 21/762; H01L 21/28

(52) U.S. Cl. 438/427; 438/589; 257/E21.158; 257/E21.546

(57) ABSTRACT

Provided are a method of forming a device isolation layer and a method of fabricating a semiconductor device. The method includes: forming a first trench and a second trench in a substrate, wherein the second trench is connected to the first trench and has a width smaller than the first trench; forming a liner insulation layer in the second trench such that the liner insulation layer is buried in the second trench; and forming a gap fill insulation layer on the liner insulation layer such that the gap fill insulation layer is buried in the first trench.

### CROSS-REFERENCE TO RELATED APPLICATIONS

This application claims the benefit of Korean Patent Application No. 10-2009-0060834, filed on Jul. 3, 2009, in the Korean Intellectual Property Office, the disclosure of which is incorporated herein in its entirety by reference.

### BACKGROUND

The inventive concept relates to a method of forming a device isolation layer and a method of fabricating a semiconductor device, and more particularly, to a shallow trench isolation (STI) layer and a method of fabricating a semiconductor device using the same.

As the integration density of semiconductor devices increases, the importance of device isolation techniques for electrically isolating adjacent devices has further increased. In particular, a shallow trench isolation (STI) layer is widely employed as a device isolation technique owing to its excellent device isolation performance in spite of its narrow width.

### SUMMARY

According to an aspect of the inventive concept, there is provided a method of forming a device isolation layer, the method including: forming a first trench and a second trench in a substrate, wherein the second trench is connected to the first trench and has a width smaller than the first trench; forming a liner insulation layer in the second trench such that the liner insulation layer is buried in the second trench; and forming a gap fill insulation layer on the liner insulation layer such that the gap fill insulation layer is buried in the first trench.

The liner insulation layer may include a silicon nitride (SiN) layer, and the gap fill insulation layer comprises a spin-on-glass (SOG) oxide layer.

The method may further include: before forming the liner insulation layer, forming a side wall insulation layer in inner walls of the first trench and the second trench.

The forming of the first trench and the second trench may include: forming a buffer layer and a mask layer on the substrate and patterning the buffer layer and the mask layer; forming a spacer insulation layer on inner walls of the buffer layer and the mask layer; etching the substrate by a predetermined depth using the spacer insulation layer as a mask; removing the spacer insulation layer; and forming the first trench and the second trench having the width smaller than the first trench by etching the substrate by a predetermined depth.

The forming of the first trench and the second trench may include: forming a buffer layer and a mask layer on the substrate and patterning the buffer layer and the mask layer; forming the first trench by etching the substrate by a predetermined depth using the buffer layer and the mask layer as a mask; forming a spacer insulation layer in an inner wall of the first trench; forming the second trench having the width smaller than the first trench by etching the substrate by a predetermined depth using the spacer insulation layer as a mask; and removing the spacer insulation layer.

The SOG oxide layer may include silicate, siloxane, methylsilsequioxane (MSQ), hydrogen silsesquioxane (HSQ), polysilazane or a combination thereof.

The method may further include: densificating the gap fill insulation layer by annealing the substrate; planarizing the gap fill insulation layer; and removing the buffer layer and the mask layer.

According to another aspect of the inventive concept, there is provided a method of forming a device isolation layer, the method including: forming a buffer layer and a mask layer on a substrate and patterning the buffer layer and the mask layer; forming a spacer insulation layer in inner walls of the buffer layer and the mask layer; etching the substrate by a predetermined depth using the spacer insulation layer as a mask; removing the spacer insulation layer; and forming a first trench and a second trench having the width smaller than the first trench by etching the substrate by a predetermined depth using the buffer layer and the mask layer as a mask.

According to another aspect of the inventive concept, there is provided a method of forming a semiconductor device, the method including: forming a first trench defining an activation region of a substrate and a second trench in a lower portion of the first trench wherein the second trench has a width smaller than the first trench; forming a side wall insulation layer in inner walls of the first trench and the second trench; forming a liner insulation layer on the side wall insulation layer such that the liner insulation layer is buried in the second trench; forming a gap fill insulation layer on the liner insulation layer such that the gap fill insulation layer is buried in the first trench; forming a gate trench in the activation region; forming a gate insulation layer in an upper portion of the gate trench; and forming a gate electrode layer in an upper portion of the gate insulation layer such that the gate electrode layer is buried in the gate trench.

A depth of the gate trench may be greater than a depth of the first trench.

### BRIEF DESCRIPTION OF THE DRAWINGS

Exemplary embodiments of the inventive concept will be more clearly understood from the following detailed description, taken in conjunction with the accompanying drawings in which:

FIG. 1A through 1I are cross-sectional views for explaining a method of forming a device isolation layer, according to an exemplary embodiment;

FIG. 2 is a cross-sectional view of a device isolation layer formed using the method of forming a device isolation layer, according to an exemplary embodiment;

FIGS. 3A and 3B are cross-sectional views of various types of device isolation layers formed using the method of forming a device isolation layer, according to an exemplary embodiment;

FIG. 4A through 4E are cross-sectional views for explaining a method of forming a device isolation layer of a semiconductor device, according to another exemplary embodiment;

FIG. 5A through 5D are cross-sectional views for sequentially explaining a method of fabricating a semiconductor device using a device isolation layer, according to an exemplary embodiment;

FIG. 6 is a plan view of a semiconductor device according to an exemplary embodiment;

FIG. 7 is a cross-sectional view of the semiconductor device of FIG. 6, taken from a line a-a′; and

FIG. 8 is a cross-sectional view of the semiconductor device of FIG. 6, taken from a line b-b′.

### DETAILED DESCRIPTION OF THE EMBODIMENTS

The attached drawings for illustrating exemplary embodiments of the inventive concept are referred to in order to gain a sufficient understanding of the inventive concept, the merits thereof, and the objectives accomplished by the implementation of the inventive concept.

The terminology used herein is for the purpose of describing particular embodiments only and is not intended to be limiting of exemplary embodiments. As used herein, the term “and/or” includes any and all combinations of one or more of the associated listed items. As used herein, the singular forms “a,” “an” and “the” are intended to include the plural forms as well, unless the context clearly indicates otherwise. It will be further understood that the terms “comprises” and/or “comprising” when used in this specification, specify the presence of stated features, integers, steps, operations, elements, and/or components, but do not preclude the presence or addition of one or more other features, integers, steps, operations, elements, components, and/or groups thereof.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of exemplary embodiments.

Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but may be to include deviations in shapes that result, for example, from manufacturing. In the drawings, lengths and sizes of layers and regions may be exaggerated for clarity. Like reference numerals in the drawings denote like elements.

As appreciated by the present inventors, in a convention approach, after a layer of a spin-on-glass (SOG) material is deposited in a trench, if the SOG material is annealed and undergoes densification, heat is well transferred in an upper portion of the trench and thus a hard SOG layer is formed. Meanwhile, since heat is not transferred in a lower portion of the trench as the greater the depth of the trench, a porous SOG layer is formed, which highly likely renders a defect in a subsequent process.

As further appreciated by the present inventors, methods of improving the characteristics of the SOG material and annealing the SOG layer at a higher temperature and during a longer period of time may be used to improve the characteristics of the porous SOG layer in the lower portion of the trench. However, such methods are disadvantageous in terms of expenses and efficiency.

As further appreciated by the present inventors, a field bursts since the SOG material is not completely cured when annealed in the lower portion of the trench. In a transistor in which a buried gate electrode layer is formed in a substrate, since a gate poly bridge is generated between gates formed in a gate trench due to the burst of the field, the gates may be short.

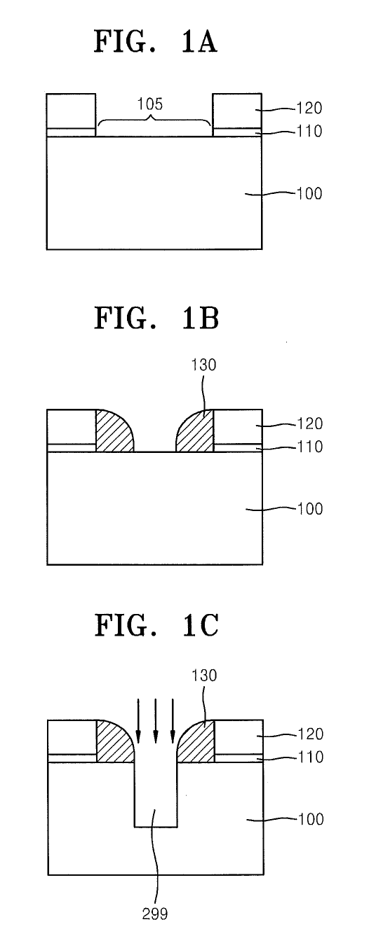

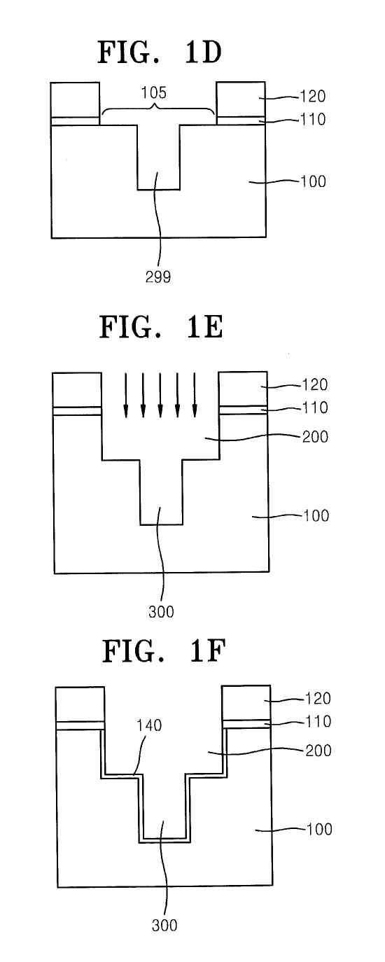

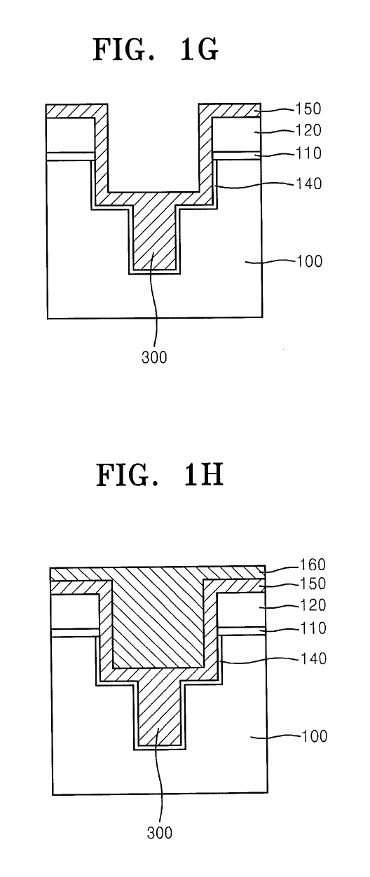

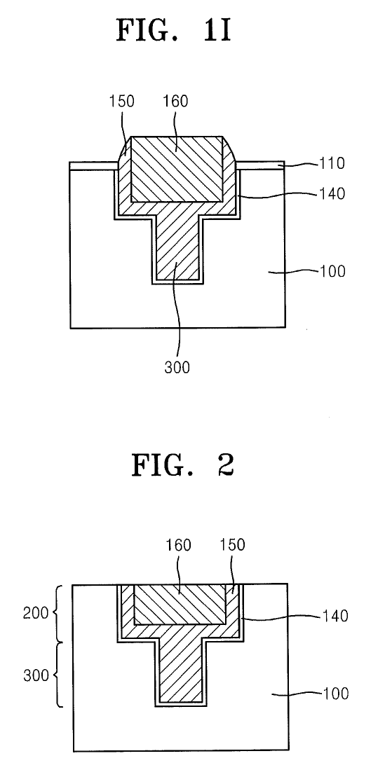

FIG. 1A through 1I are cross-sectional views for explaining a method of forming a device isolation layer, according to an exemplary embodiment. Referring to FIG. 1A, a buffer layer 110 and a mask layer 120 are sequentially formed on a semiconductor substrate 100, such as a silicon substrate, a silicon-germanium (Si—Ge) substrate, or a silicon-on-insulation (SOI) substrate. The buffer layer 110 and the mask layer 120 may have an etching selection ratio with respect to each other. For example, the buffer layer 110 may be an oxide layer having a thickness less than about 150 Å through an annealing process. The mask layer 120 may be a nitride layer having a thickness between about 200 Å and about 1000 Å through a chemical vapor deposition (CVD) process. The buffer layer 110 and the mask layer 120 are patterned and thus a device isolation region 105 is exposed.

Referring to FIG. 1B, a spacer insulation layer 130 is formed on the inner walls of the buffer layer 110 and the mask layer 120. For example, the spacer insulation layer 130 may be an oxide layer deposited through a CVD process or may be formed through an anisotropic plasma etch back process. Since the oxide layer deposited on the inner walls of the buffer layer 110 and the mask layer 120 is relatively thick, the deposited oxide layer remains after being etched as the spacer insulation layer 130. Referring to FIG. 1C, a temporary trench 299 is formed in the semiconductor substrate 100 by etching the semiconductor substrate 100 by a predetermined depth using the mask layer 120 and the spacer insulation layer 130 as a mask. The temporary trench 299 is etched by using the spacer insulation layer 130 formed on a side surface of the device isolation region 105 as the mask and thus a width of the temporary trench 299 is smaller than a width of the device isolation region 105.

Referring to FIG. 1D, the device isolation region 105 is exposed by removing the spacer insulation layer 130. Referring to FIG. 1E, the semiconductor substrate 100 is etched by a predetermined depth using the buffer layer 110 and the mask layer 120 as the mask, thereby forming a double-trenched structure including a first trench 200 and a second trench 300. Referring to FIG. 1F, a sidewall insulation layer 140 is formed on an inner wall of the first trench 200 and the second trench 300. For example, the sidewall insulation layer 140 may be an oxide layer formed by oxidizing the surface of the semiconductor substrate 100 that is exposed in the first trench 200 and the second trench 300 by a predetermined depth through the annealing process. In particular, a thickness of the sidewall insulation layer 140 may be between about 20 Å and 150 Å. Referring to FIG. 1G, a liner insulation layer 150 is formed on the sidewall insulation layer 140. The liner insulation layer 150 may be, for example, a silicon nitride (SiN) layer having a thickness of at least 50 Å. Also, the liner insulation layer 150 may be buried in the second trench 300. The liner insulation layer 150 may be formed to absorb stress due to a difference in a thermal expansion coefficient between a gap fill insulation layer (not shown) that is to fill the first trench 200 and the sidewall insulation layer 140. Referring to FIG. 1H, the gap fill insulation layer 160 is formed on the liner insulation layer 150. The gap fill insulation layer 160 may be buried in the first trench 200. The gap fill insulation layer 160 may be a spin-on-glass (SOG) oxide layer formed of silicate, siloxane, methylsilsequioxane (MSQ), hydrogen silsesquioxane (HSQ), polysilazane or a combination thereof. The SOG oxide layer has a network structure including elements such as silicone, oxygen, hydrogen, nitrogen, and the like and has a good flow and thus the gap fill insulation layer 160 has very excellent gap filling characteristics. The quality of the gap fill insulation layer 160 is improved by densification of the gap fill insulation layer 160, for example, by annealing the semiconductor substrate 100 including the gap fill insulation layer 160. The semiconductor substrate 100 may be annealed in an atmosphere of N₂ or in a steam atmosphere. Referring to FIG. 1I, the gap fill insulation layer 160 is removed through a chemical-mechanical polishing (CMP) process or an etch back process and an upper portion of the mask layer 120 may be exposed. The mask layer 120 may be removed through a strip process using a phosphoric acid solution.

FIG. 2 is a cross-sectional view of a device isolation layer formed using the method of forming a device isolation layer, according to an exemplary embodiment.

Referring to FIG. 2, the device isolation layer of the present embodiment includes the semiconductor substrate 100 and a double-trenched structure including the first and second trenches 200 and 300 formed in the device isolation region 105 of the semiconductor substrate 100. The device isolation layer includes the first trench 200 and the second trench 300 having a width smaller than the first trench 200. The device isolation layer may include the sidewall insulation layer 140 covering the inner walls of the first trench 200 and the second trench 300 and include the liner insulation layer 150 formed on the sidewall insulation layer 140. The liner insulation layer 150 may be buried in the second trench 300. The device isolation layer may include the gap fill insulation layer 160 buried in the first trench 200 formed on the liner insulation layer 140.

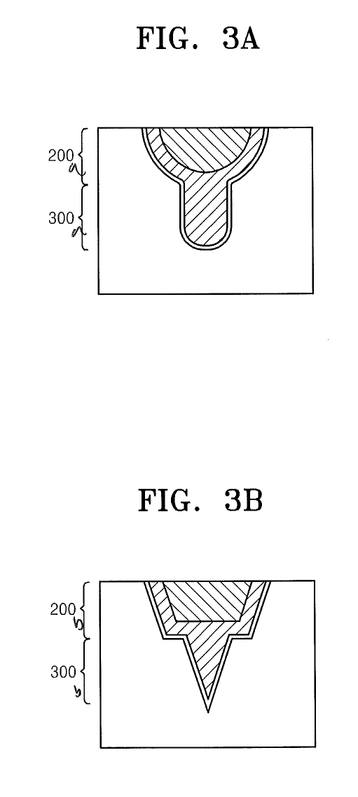

FIGS. 3A and 3B are cross-sectional views of various types of device isolation layers formed using the method of forming a device isolation layer, according to exemplary embodiment.

Referring to FIGS. 3A and 3B, the device isolation layers of the present embodiment may be formed in various ways. In more detail, the device isolation layers may each include two first trenches 200a and 200b and two second trenches 300a and 300b in the shape of a rectangle, an oval, and a triangle (trapezoid) formed through a dry and wet etching process or an isotropic and anisotropic etching process. Although not shown, for example, the first trenches 200a and 200b may be in the form of a trapezoid, and the second trenches 300a and 300b may be in the form of a rectangle.

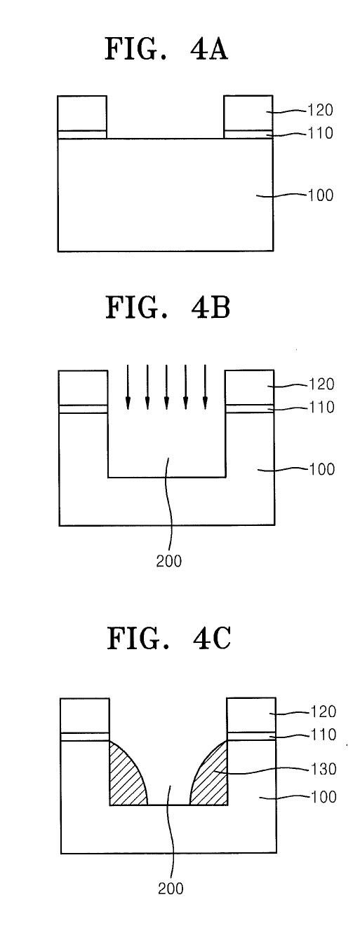

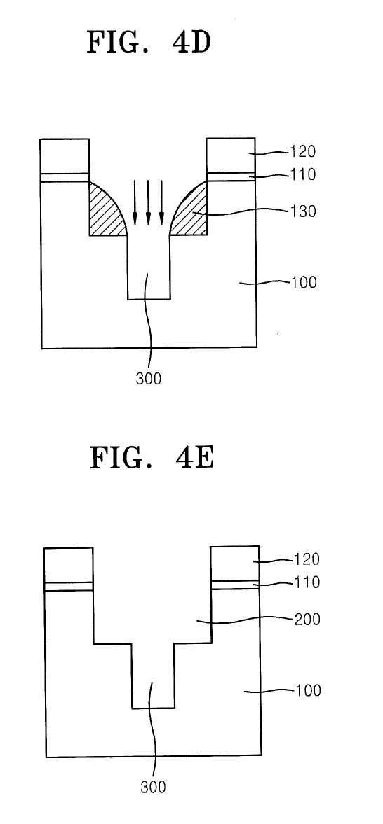

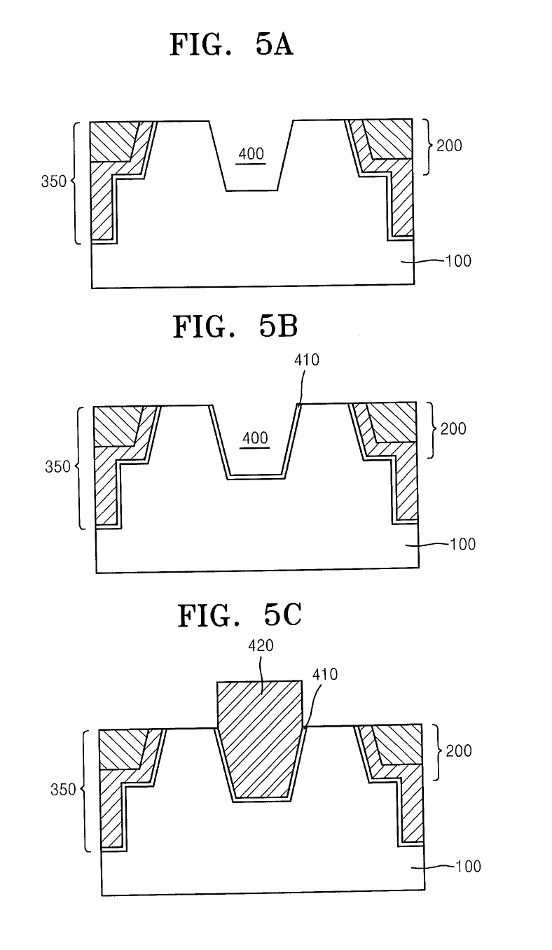

FIG. 4A through 4E are cross-sectional views for explaining a method of forming a device isolation layer of a semiconductor device, according to another exemplary embodiment. The method of forming the device isolation layer of the semiconductor device of the present embodiment is the same as the method of forming the device isolation layer described with reference to FIGS. 1A through 1H, except for the process of forming the double-trenched structure shown in FIGS. 1A through 1E. The same descriptions between the previous and present embodiments will not be repeated here.

Referring to FIG. 4A, the buffer layer 110 and the mask layer 120 that are patterned are sequentially formed on the semiconductor layer 100. Referring to FIG. 4B, the first trench 200 is formed by etching the semiconductor substrate 100 by a predetermined depth using the buffer layer 110 and the mask layer 120 as a mask. Referring to FIG. 4C, the spacer insulation layer 130 is formed on the inner wall of the first trench 200. Referring to FIG. 4D, the second trench 300 is formed by etching the semiconductor substrate 100 by a predetermined depth using the mask layer 120 and the spacer insulation layer 130 as a mask. Referring to FIG. 4E, a double-trenched structure including the first trench 200 and the second trench 300 is formed by removing the spacer insulation layer 130. The first trench 200 is formed by etching the semiconductor substrate 100 by a predetermined depth using the buffer layer 110 that is a pad oxide layer and the mask layer 120 as the mask, whereas the second trench 300 is formed by etching the semiconductor substrate 100 by a predetermined depth using the space insulation layer 130 as the mask. Thus, a width of the second trench 300 is smaller than a width of the first trench 200. Alternatively, when a device isolation layer is formed, thereby defining an activation region of a transistor in which a recess or buried gate structure (not shown) is formed, a depth of the first trench 200 may be smaller than a depth of the recess or buried gate structure (not shown). Alternatively, the depth of the first trench 200 may be less than 1000 Å, and a depth of the second trench 300 may be between 1000 Å and 3000 Å with respect to the depth of the first trench 200.

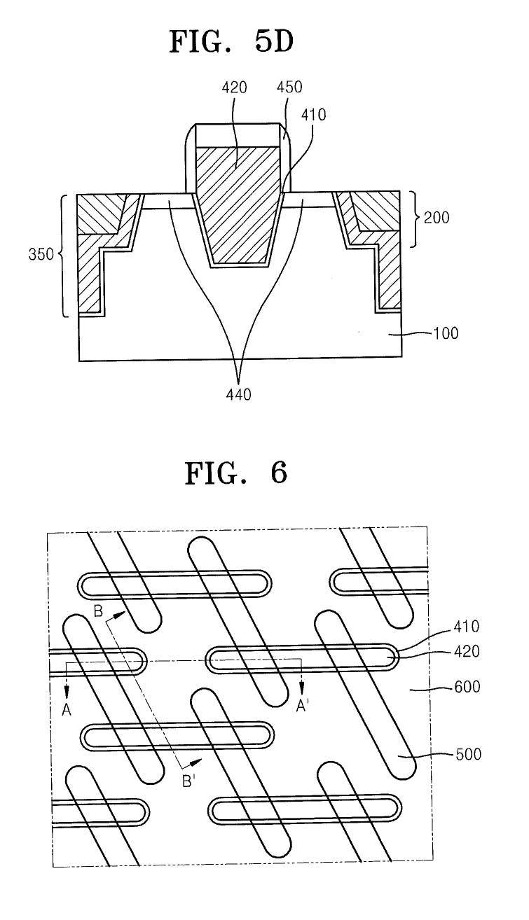

FIG. 5A through 5D are cross-sectional views for sequentially explaining a method of fabricating a semiconductor device using a device isolation layer 350, according to an exemplary embodiment.

Referring to FIG. 5A, a gate trench 400 is formed in order to form a recess channel (not shown) in an activation region defined by the device isolation layer 350. A depth of the gate trench 400 may be greater than a depth of the first trench 200, and, in particular, the depth of the gate trench 400 may be at least 1500 Å. A plurality of the gate trenches 400 may be formed in the activation region defined by the device isolation layer 350. A buffer insulation layer (not shown) such as a silicone oxide layer or a hard disk layer (not shown) such as a polysilicon layer or a nitride layer may be formed on the upper surface of the activation region in order to form the gate trench 400. Referring to FIG. 5B, a gate insulation layer 410 is formed in the gate trench 400. The gate insulation layer 410 may be a thermal oxide layer formed through a thermal oxidation process. Referring to FIG. 5C, a gate electrode layer 420 is formed on the gate insulation layer 410. The gate electrode layer 420 may be formed through a CVD process or an atomic later deposition (ALD) process. The gate electrode layer 420 may protrude from a top surface of the semiconductor substrate 100. Referring to FIG. 5D, a capping layer 430 (not shown) is formed on an upper portion of the gate electrode layer 420. Thereafter, a source and drain region 440 are formed between the gate trench 400 and the device isolation layer 350 through an ion injection process, and a spacer insulation layer 450 is formed on a side portion of the gate electrode layer 420.

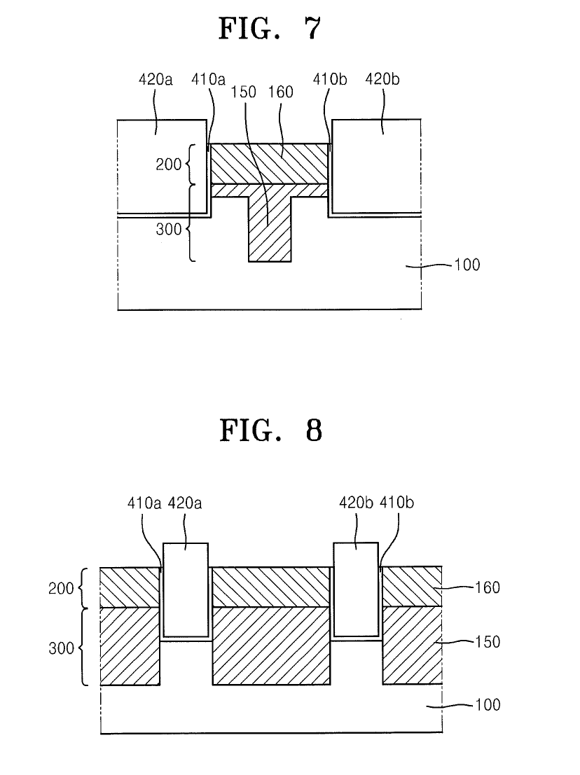

FIG. 6 is a cross-sectional view of a semiconductor device according to an exemplary embodiment. FIG. 7 is a cross-sectional view of the semiconductor device of FIG. 6, taken from a line a-a′. FIG. 8 is a cross-sectional view of the semiconductor device of FIG. 6, taken from a line b-b′.

Referring to FIGS. 6 through 8, a device isolation layer 600 is formed on a semiconductor substrate and a remaining region of the semiconductor substrate is defined as an activation region 500. Thereafter, a mask layer pattern (not shown) is formed on the semiconductor substrate including the device isolation layer 600 and the activation region 500. A gate trench is formed by etching the semiconductor substrate by a predetermined depth using the mask layer pattern as a mask. A depth of the gate trench may be greater than the depth of the first trench 200 of the device isolation layer 600, as shown in FIG. 5A. The gate insulation layer 410 and the gate electrode layer 420 are formed on the upper portion of the gate trench. Referring to FIGS. 7 and 8, the gate trench is formed by etching the mask layer pattern (not shown) after the device isolation layer 200 and 300 is formed, and gate insulation layers 410a and 410b and gate electrode layers 420a and 420b are formed in an upper portion of the gate trench.

Since an SOG oxide layer is formed in the upper portion of the device isolation layer 600, i.e., the first trench 200, heat is well transferred to the SOG oxide layer through a thermal treatment process and thus the gap fill insulation layer 160 may become hard. That is, the device isolation layer 600 of the semiconductor device is formed of an SOG material having excellent gap fill performance, which is advantageous in terms of fabricating cost and efficiency. In addition, there is no SOG material but the liner insulation layer 150 is formed in the lower portion of the device isolation layer 600, i.e. the second trench 300. Thus, a porous SOG layer is not formed due to a burst of the field even though heat is not transferred to the liner insulation layer 150 as the greater the depth of the second trench 300. That is, the liner insulation layer 150 formed in the lower portion of the device isolation layer 600 prevents a gate poly bridge from being generated between the gate electrode layers 420a and 420b. Although not shown, the device isolation layer 600 of the present embodiment may be used in a recess channel cell array transistor, a buried wordline cell array transistor (BCAT), and a transistor having a buried gate structure.

While the inventive concept has been particularly shown and described with reference to exemplary embodiments thereof, it will be understood that various changes in form and details may be made therein without departing from the spirit and scope of the following claims.

What is claimed is:

1. A method of forming a device isolation layer, the method comprising:
forming a first trench and a second trench in a substrate, wherein the second trench is connected to the first trench and has a width smaller than the first trench;
forming a liner insulation layer in the second trench such that the liner insulation layer is buried in the second trench; and
forming a gap fill insulation layer on the liner insulation layer such that the gap fill insulation layer is buried in the first trench.

2. The method of claim 1, wherein the liner insulation layer comprises a silicon nitride (SiN) layer, and the gap fill insulation layer comprises a spin-on-glass (SOG) oxide layer.

3. The method of claim 1, further comprising: before forming the liner insulation layer, forming a side wall insulation layer in inner walls of the first trench and the second trench.

4. The method of claim 1, wherein the forming of the first trench and the second trench comprises:
forming a buffer layer and a mask layer on the substrate and patterning the buffer layer and the mask layer;
forming a spacer insulation layer on inner walls of the buffer layer and the mask layer;
etching the substrate to a first predetermined depth using the spacer insulation layer as a mask;
removing the spacer insulation layer; and
forming the first trench and the second trench having by etching the substrate to a second predetermined depth.

5. The method of claim 1, wherein the forming of the first trench and the second trench comprises:
forming a buffer layer and a mask layer on the substrate and patterning the buffer layer and the mask layer;
forming the first trench by etching the substrate to a first predetermined depth using the buffer layer and the mask layer as a mask;
forming a spacer insulation layer in an inner wall of the first trench;
forming the second trench by etching the substrate to a second predetermined depth using the spacer insulation layer as a mask; and
removing the spacer insulation layer.

6. The method of claim 2, wherein the SOG oxide layer comprises silicate, siloxane, methylsilsequioxane (MSQ), hydrogen silsesquioxane (HSQ), polysilazane or a combination thereof.

7. The method of claim 1, further comprising:
densificating the gap fill insulation layer by annealing the substrate;
planarizing the gap fill insulation layer; and
removing the buffer layer and the mask layer.

8. A method of forming a device isolation layer, the method comprising:
forming a buffer layer and a mask layer on a substrate and patterning the buffer layer and the mask layer;
forming a spacer insulation layer in inner walls of the buffer layer and the mask layer;
etching the substrate to a first predetermined depth using the spacer insulation layer as a mask;
removing the spacer insulation layer; and
forming a first trench and a second trench having a width smaller than the first trench by etching the substrate to a second predetermined depth using the buffer layer and the mask layer as a mask.

9. A method of forming a semiconductor device, the method comprising:
forming a first trench defining an activation region of a substrate and a second trench in a lower portion of the first trench wherein the second trench has a width smaller than the first trench;
forming a side wall insulation layer in inner walls of the first trench and the second trench;
forming a liner insulation layer on the side wall insulation layer such that the liner insulation layer is buried in the second trench;
forming a gap fill insulation layer on the liner insulation layer such that the gap fill insulation layer is buried in the first trench;
forming a gate trench in the activation region;
forming a gate insulation layer in an upper portion of the gate trench; and
forming a gate electrode layer in an upper portion of the gate insulation layer such that the gate electrode layer is buried in the gate trench.

10. The method of claim 9, wherein a depth of the gate trench is greater than a depth of the first trench.

11. A method of forming a device isolation layer, the method comprising:
forming a first trench in a substrate having a hardened SOG material formed in and limited to the first trench; and
forming a second trench, narrower than an opening of the first trench, in a bottom surface of the first trench and having a liner insulation layer formed on a side wall thereof comprising an SOG material, wherein other SOG materials are absent from inside the second trench.
